(19) United States
(12) Patent Application Publication
(10) Pub. No.: US 2015/0129847 A1
(43) Pub. Date: May 14, 2015

(54) METHOD FOR PRODUCING CONDUCTIVE SUBSTRATE, CONDUCTIVE SUBSTRATE, AND ORGANIC ELECTRONIC ELEMENT

(71) Applicant: Konica Minolta, Inc., Tokyo (JP)

(72) Inventors: Hiroshi Takada, Hachioji-shi (JP); Toshiyuki Matsumura, Sagamihara-shi (JP); Masaki Goto, Hino-shi (JP)

(21) Appl. No.: 14/399,722

(22) PCT Filed: May 16, 2013
(86) PCT No.: PCT/JP2013/063621

§ 371 Date: Nov. 7, 2014

(30) Foreign Application Priority Data
May 18, 2012 (JP) 2012-114061

(51) Int. Cl. H01L 51/00; H05K 1/03; H05K 1/02; H05K 3/10

(52) U.S. Cl. CPC H01L 51/0096; H01L 51/0022; H05K 3/10; H05K 1/0306; H05K 1/0271; H01L 51/44
USPC 257/40; 427/559; 174/258

(57) ABSTRACT

A method for producing a conductive substrate including at least an anchor layer and a pattern of conductive thin metal lines on a bare substrate is provided. The method includes the steps of: forming a porous anchor layer mainly composed of an inorganic compound on the bare substrate; forming the pattern of thin metal lines containing metal nanoparticles and a metal complex on the anchor layer; and performing thermal annealing of the pattern of thin metal lines by irradiation of flash light.

### TECHNICAL FIELD

The present invention relates to a method for producing a conductive substrate, a conductive substrate, and an organic electronic element for an organic electronic device such as an organic electroluminescent (EL) device using the conductive substrate, and a solar cell.

### BACKGROUND ART

There have been invented, as methods for producing conductive substrates having patterned thin metal lines, a subtractive method and an additive method, and they have been extensively used because of their high reliability. Conductive substrates have been recently used in a variety of electronic apparatuses/devices, and have required higher density of patterned thin metal lines to meet higher-performance apparatus/devices. These methods usually employ photolithographic processes suitable for microfabrication to form desired patterns of thin metal lines.

In a photolithographic process, a resist is applied over an entire substrate, and the substrate is prebaked. The substrate with the resist is then irradiated with ultraviolet light through a photomask so that a resist pattern is formed by development. Then, etching is performed along the resist pattern, which functions as a mask, to remove unnecessary portions to form patterned thin metal lines. However, such steps of patterning thin metal lines in the conventional photolithographic process waste most of a metal film for patterning and a resist material. Furthermore, the photoresist process, which has many steps, has low throughput.

With such a background, production of patterns of thin metal lines by printing has been attempted in recent years. For example, production of conductive substrates has been extensively examined through application of ink containing conductive metal particles by a variety of printing processes, such as screen printing and inkjet printing, to form conductive layers and/or insulating layers (for example, see Patent Literature 1). Specifically, a pattern of metal nanoparticles is drawn by printing with an ink composition containing dispersed nanoparticles of a metal, such as silver, gold, or copper, and the metal nanoparticles are calcined or annealed to prepare a conductive substrate having patterned thin metal lines.

However, this method needs a heat treatment at 200° C. or more to anneal the metal nanoparticles to establish an electrically conducted pattern of metal nanoparticles, and thus cannot be readily applied to inexpensive resin bare substrates having low heat resistance. Thin bare substrates having high heat resistance, such as glass bare substrates and metal bare substrates, may warp or strain during heat treatment at such high temperatures, precluding in thinning in profile. A lower heat treating temperature to avoid thermal damage to the bare substrate requires a longer time for annealing of metal nanoparticles, resulting in low throughput.

A proposed method for solving the problems involves annealing patterned conductive thin metal lines composed of metal nanoparticles by heat of flashed light (for example, see Patent Literature 2).

Disposition of a PEDOT/PSS layer on patterned thin metal lines annealed by local heating has also been reported (for example, see Non-Patent Literature 1). The disposition of a conductive polymer layer on patterned thin metal lines improves the smoothness of the surface of a transparent electrode, and can prevent leakage of current between electrodes in application to organic electronic devices.

Light-emitting electronic display devices include electroluminescent displays (hereinafter referred to as ELD). The components of the ELD include inorganic electroluminescent elements and organic electroluminescent elements (hereinafter also referred to as organic EL elements). Although the inorganic electroluminescent elements have been used as planar light sources, high AC voltage is necessary for driving a light emitting element. In the organic EL elements, a luminous layer containing a light-emitting compound is interposed between a cathode and an anode. Electrons and holes are injected into the luminous layer to recombine these electrons and holes to generate excitons. The excitons, when deactivated, emit light (fluorescence and/or phosphorescence). The organic EL elements emit light from the excitons. The organic EL elements can emit light at about several volts to several tens of volts. The thin-film self-luminescent completely solid-state elements have a wide viewing angle and high visibility, and attain reductions in space and portability. The organic EL elements have been attracting attention for these characteristics, and have been expected not only in applications to self-luminescent displays but also backlights for liquid crystal displays and lighting.

However, organic EL elements that can emit light at lower power and higher luminance with higher efficiency should be developed to put the organic EL element into practical use.

The light-emitting efficiency of the organic EL element is composed of internal efficiency and external efficiency (or light extraction efficiency). The organic EL element cannot have high light extraction efficiency because the light partially reflects at interfaces between layers laminated to form the organic EL element, such as a bare substrate, electrodes, and a luminous layer, to be confined inside the element.

### CITATION LIST

### Patent Literature

Patent Literature 1: Japanese Patent Laid-open Publication No. 2007-332347

Patent Literature 2: Japanese Unexamined Patent Application Publication (Translation of PCT Application) No. 2008-522369

### Non-Patent Literature

Non-Patent Literature 1: Organic PhotoVoltaics, Open Innovation Program ECN-Holst Centre, Netherlands, Large-area, Organic & Printed Electronics Convention, Jun. 2, 2010, Ronn Andriessen.

### SUMMARY OF INVENTION

### Problems to be Solved by Invention

The method of thermally annealing patterned thin metal lines by flashed light according to Patent Literature 2 can locally heat the patterned thin metal lines to a high temperature to improve conductivity effectively while the patterned thin metal lines reach very high temperatures. Such a high temperature readily damages the bare substrate at and near the interfaces between the patterned thin metal lines and the bare substrate. In particular, for a resin bare substrate having low heat resistance, patterned thin metal lines cannot be readily annealed with reduced damage to the bare substrate, resulting in insufficient improvements in conductivity.

According to Patent Literature 2, to solve the problem, a metal film can be annealed without damaging a bare substrate under specific irradiation conditions on flash light (areal energy density and pulse length). However, this approach should establish the irradiation conditions by trial and error according to the type (material and shape) of patterned thin metal lines and the type of a bare substrate to be used, and requires much effort.

An improvement in the conductivity of the patterned thin metal lines requires high energy of the flash light to be emitted while the patterned thin metal lines are unintendedly blown off from the bare substrate by irradiation with high-energy flash light, and the patterned thin metal lines cannot be sufficiently annealed without being damaged.

Such damage might be caused because the patterned thin metal lines are instantly heated to a high temperature by high-energy flash light to instantly evaporate organic substances remaining inside the thin metal lines, such as a dispersant and a solvent in an ink used to dispose the patterned thin metal lines.

To solve the problem, Patent Literature 2 proposes a reduction in thickness of a metal film and a method of annealing patterned thin metal lines in vacuum with flash light (Example 12). The thickness of the metal film, however, should be designed according to the performance required for the patterned thin metal lines, and should not be limited by the annealing method. The method of annealing patterned thin metal lines in vacuum with flash light is not preferred because the method increases facility costs and reduces productivity.

Patent Literature 2 proposes and implements another method that involves addition of a binder to an ink containing a metal (Example 13) for solving the problem. Use of such an additive reduces the conductivity of patterned thin metal lines after irradiation of flash light more significantly than that of patterned thin metal lines without a binder.

Patent Literature 2 also proposes a method of irradiating patterned thin metal lines with flash light several times wherein a gas causing separation of or damage to a metal film is discharged by initial irradiation of flash light, and the patterned thin metal lines are sufficiently annealed by irradiation of flash light having higher intensity than in the initial flashing (see Example 15). However, the metal film has been annealed to some extent at the stage of irradiation with the flash light having high intensity and thus has increased thermal conductivity, and the surface of the bare substrate in contact with the metal film has also reached a high temperature by the irradiation with the flash light having high intensity. Consequently, this method cannot be applied to resin bare substrates having low heat resistance.

In consideration of the problems, an object of the present invention is to provide a method for producing a conductive substrate that can produce a highly conductive substrate with less or no damage to its bare substrate and patterned thin metal lines.

Another object of the present invention is to improve the light extraction efficiency of an organic electronic element, such as organic EL elements having superior characteristics as a planer light-emitting member.

### Means for Solving Problems

The present inventor, who has conducted extensive research on the problems and their causes, has unexpectedly found that when thin metal lines containing metal nanoparticles and/or a metal complex are patterned and the patterned thin metal lines are annealed by irradiation with flash light, a porous anchor layer mainly composed of an inorganic compound and disposed on a bare substrate can improve the conductivity of the patterned thin metal lines and prevent or reduce damage to the bare substrate and the patterned thin metal lines, and has achieved the present invention.

If a porous anchor layer mainly composed of an organic compound is disposed, the anchor layer is readily damaged by irradiation of flash light. If irradiation of high-energy flash light is performed to improve the conductivity of the patterned thin metal lines, the same effect as in the anchor layer according to the present invention cannot be attained.

It is well known that a porous ink receiving layer is disposed on a bare substrate to improve absorption of ink during printing by an inkjet process, and several methods have been proposed.

Examples of the methods include a method of disposing a porous layer containing porous particles, such as diatomite and perlite powder, on a support (Japanese Patent Laid-open Publication No. S61-8385); a method of dissolving a plastic substance in a less miscible solvent, applying the resulting solution to a bare substrate, and solidifying the plastic substance in a solidifying bath to dispose a porous layer (Japanese Patent Laid-open Publication No. S62-197183); a method of disposing a porous layer composed of a hydrophilic inorganic-organic composite containing colloidal silica particles on a bare substrate (Japanese Patent Laid-open Publication No. H2-147233); a method of disposing an ink receiving film containing metal oxide particles and a hydrolyzed condensate of an alkoxide compound (Japanese Patent Laid-open Publication No. 2007-169604); and a method of disposing an ink receiving film containing metal oxide particles and a polyimide precursor (Japanese Patent Laid-open Publication No. 2010-161118).

However, these techniques do not describe the problems to be solved in the present invention or suggest any solution to the problems.

In view of the above situation, according to the present invention, there is provided A method for producing a conductive substrate including at least an anchor layer and a pattern of conductive thin metal lines on a bare substrate, the method including the steps of: forming a porous anchor layer mainly composed of an inorganic compound on the bare substrate; forming the pattern of thin metal lines containing metal nanoparticles and a metal complex on the anchor layer; and performing thermal annealing of the pattern of thin metal lines by irradiation of flash light.

The above method for producing the conductive substrate can reduce damage to the bare substrate during annealing of the patterned thin metal lines by the irradiation with flash light, and can produce a highly conductive substrate without damage to the patterned thin metal lines.

The producing method according to the present invention can prevent damage to the bare substrate by irradiation of high-energy flashlight even in resin bare substrates having low heat resistance. This advantageous effect is attained probably because the porous anchor layer according to the present invention effectively functions as a heat insulating layer between the bare substrate and the patterned thin metal lines.

The patterned thin metal lines are blown off from the bare substrate or damaged by irradiation of high-energy flash light probably because the patterned thin metal lines are instantly heated to a high temperature by the irradiation of flash light to instantly evaporate organic substances remaining inside the thin metal lines, such as a dispersant and a solvent in an ink used to dispose the patterned thin metal lines.

The producing method according to the present invention can prevent separation of or damage to the patterned thin metal lines even during irradiation of high-energy flash light. This is because the porous anchor layer according to the present invention can diffuse gas generated during instantaneous evaporation of organic substances, such as a dispersant and a solvent in an ink, through the pores of the porous anchor layer to surrounding areas of the patterned thin metal lines, i.e., reduce an impact (or disperse the pressure) of the gas on the patterned thin metal lines.

The porous anchor layer has a large area bonded to the patterned thin metal lines. Probably, such a large bonding area can effectively prevent separation of the patterned thin metal lines.

The anchor layer according to the present invention, which is mainly composed of an inorganic compound, is not damaged by the irradiation of high-energy flash light.

As described above, the anchor layer according to the present invention has functions and effects quite different from the known functions and effects of the ink receiving layer for improving the absorption of an ink.

The present inventor has also found a surprising effect that an organic EL element including a conductive substrate prepared by the method according to the present invention as a transparent electrode has light extraction efficiency higher than that of a typical organic EL element including an ITO substrate as an electrode. The method according to the present invention attains such higher light extraction efficiency while the techniques related to the ink receiving layer in the related art do not mention to such an effect at all.

### Effects of Invention

The present invention can prepare a highly conductive substrate with less or no damage to its bare substrate and patterned thin metal lines.

### BRIEF DESCRIPTION OF THE DRAWINGS

FIG. 1 is a sectional view illustrating a schematic configuration of a conductive substrate.

FIG. 2A is a sectional view for describing a step of a method for producing a conductive substrate.

FIG. 2B is a sectional view for describing the step subsequent to the step in FIG. 2A.

FIG. 2C is a sectional view for describing the step subsequent to the step in FIG. 2B.

FIG. 2D is a sectional view for describing the step subsequent to the step in FIG. 2C.

FIG. 3 is a sectional view illustrating a schematic configuration of an organic electronic element.

### MODES FOR CARRYING OUT THE INVENTION

The present invention, components thereof, and embodiments and examples for implementing the present invention will now be described in detail. In this application, the term “to” indicating the numerical range is meant to be inclusive of the boundary values.

### [Conductive Substrate (1)]

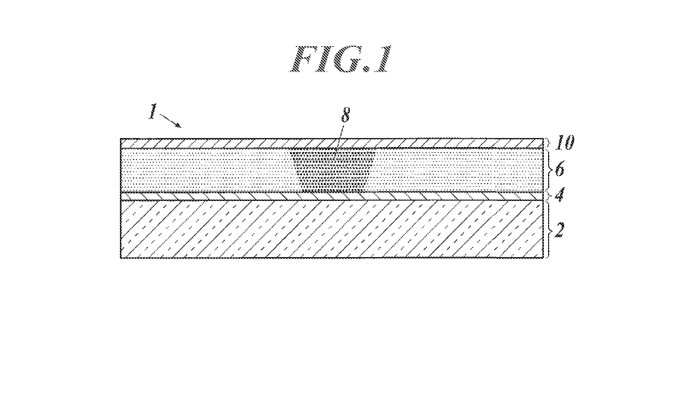

As illustrated in FIG. 1, a conductive substrate 1 according to a preferred embodiment of the present invention includes a bare substrate 2, an anchor layer 6, and a patterned thin metal line 8. At least the anchor layer 6 and the patterned conductive thin metal line 8 are disposed on the bare substrate 2.

Specifically, the anchor layer 6 is disposed on the bare substrate 2, and the patterned thin metal line 8 is disposed inside the anchor layer 6. The anchor layer 6 is a porous layer mainly composed of an inorganic compound. The patterned thin metal line 8 is composed of metal nanoparticles and a metal complex. The patterned thin metal line 8 is thermally annealed by irradiation of flash light.

The conductive substrate 1 preferably includes the bare substrate 2 composed of a transparent resin. More preferably, the conductive substrate 1 includes an additional transparent barrier layer 4 disposed between the bare substrate 2 and the anchor layer 6. Most preferably, the conductive substrate 1 includes a transparent bare substrate 2, a transparent anchor layer 6, and a transparent barrier layer 4.

In the conductive substrate 1, a conductive polymer layer 10 is preferably disposed on the anchor layer 6 and the patterned thin metal line 8 to improve the smoothness of the surface of the conductive substrate 1 and prevent leakage of current between electrodes if the conductive substrate 1 is used in an organic electronic element.

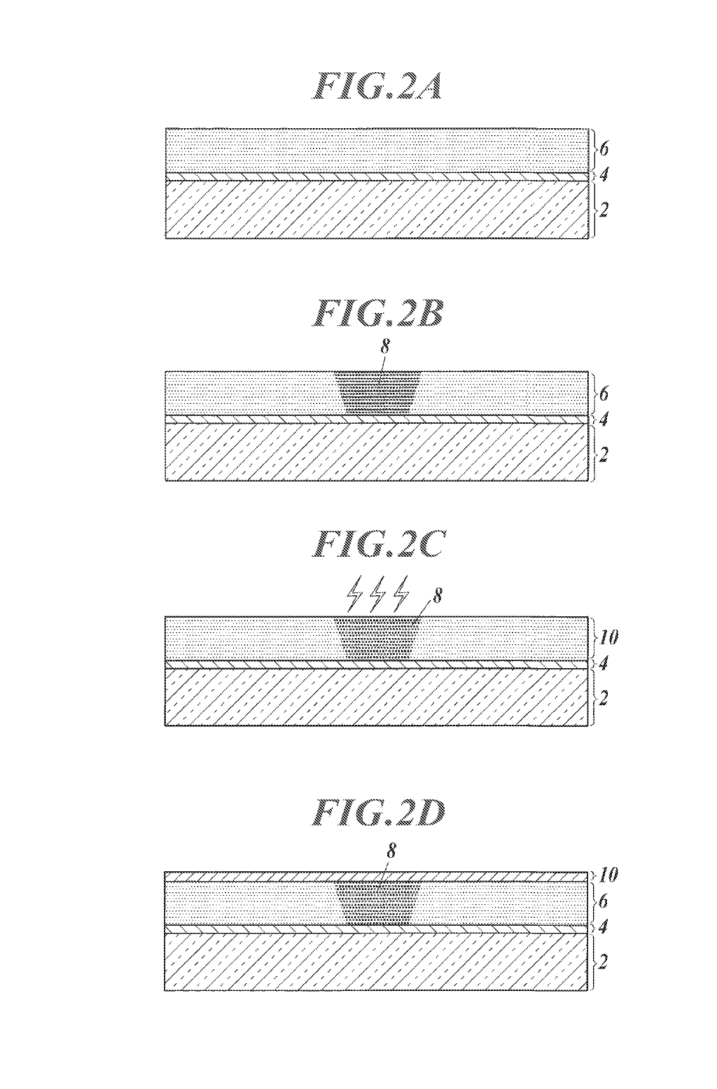

The conductive substrate 1 is prepared basically by (i) forming an anchor layer 6 on a bare substrate 2 (see FIG. 2A), (ii) then forming a patterned thin metal line 8 on the anchor layer 6 (see FIG. 2B), and (iii) finally, thermally annealing the patterned thin metal line 8 by irradiation of flash light (see FIG. 2C).

A barrier layer 4, if necessary, is formed on the bare substrate 2 before an anchor layer 6 is formed, and then the anchor layer 6 is disposed on the barrier layer 4 (see FIG. 2A).

A conductive polymer layer 10, if necessary, is formed on the anchor layer 6 and the patterned thin metal line 8 after the thermal annealing of the patterned thin metal line 8 (see FIG. 2D).

The configurations and properties of the individual members of the conductive substrate and the method of producing the members will now be described.

### [Substrate (2)]

The conductive substrate according to the present invention may be composed of any bare substrate on which an anchor layer and patterned thin metal lines according to the present invention can be formed. A glass bare substrate or a resin bare substrate can be properly selected according to applications.

The bare substrate according to the present invention can have any transparency selected according to application. Highly transparent bare substrates are preferred because they can be used in a wide variety of applications, such as transparent electrodes.

For example, transparent glass bare substrates and transparent resin bare substrates or films are preferably used. More preferred are transparent resin bare substrates from the viewpoint of high productivity, and lightweight and flexible characteristics.

The bare substrate according to the present invention desirably has a total light transmittance of 70% or more, preferably 80% or more. The total light transmittance can be measured by a known method with a spectrophotometer.

Any transparent resin film can be preferably used, and its material, shape, structure, and thickness can be properly selected from those of known transparent resin films.

Examples of materials for the transparent resin film include polyester resins, such as polyethylene terephthalate (PET), polyethylene naphthalate (PEN), and modified polyester; polyolefin resins, such as polyethylene (PE), polypropylene (PP), polystyrene, and cyclic olefins; vinyl resins, such as polyvinyl chloride and polyvinylidene chloride; polyether ether ketone (PEEK) resins; polysulfone (PSF) resins; polyether sulfone (PES) resins; polycarbonate (PC) resins; polyamide resins; polyimide resins; acrylic resins; and triacetylcellulose (TAC) resins. Any resin film having a transmittance of 80% or more at a wavelength of visible light (380 to 780 nm) can be preferably used for the transparent resin film according to the present invention.

Among these, biaxially drawn films of polyester resins, such as polyethylene terephthalate, polyethylene naphthalate, polyether sulfone, and polycarbonate, are preferred, and biaxially drawn polyethylene terephthalate and polyethylene naphthalate resin films are more preferred, because of transparency, heat resistance, ease in handling, strength, and cost.

### [Anchor Layer (6)]

The anchor layer according to the present invention is used to prevent damage to the bare substrate and the patterned thin metal lines by irradiation of flash light onto the thin metal lines and prevent thermal damage to the resin bare substrate.

The anchor layer is a porous layer mainly composed of an inorganic compound.

Throughout the specification, the term “inorganic compound” indicates a compound which is not organic, as generally understood. Specifically, the inorganic compounds include some simple carbon compounds and compounds composed of elements other than carbon.

The inorganic compound that forms the anchor layer according to the present invention is oxide, carbide, nitride, and boride of at least one metal. Examples of such a metal include magnesium, aluminum, silicon, titanium, zinc, yttrium, zirconium, molybdenum, tin, barium, and tantalum. The anchor layer according to the present invention preferably comprises at least one transparent metal oxide.

The term “porous” as one of the features of the anchor layer indicates that the specific surface area per unit area determined by a nitrogen adsorption method (BET single-point method) is 30 cm²/cm² or more.

To effectively reduce damage to the thin metal lines by irradiation of flash light onto the patterned thin metal lines, the anchor layer according to the present invention preferably has a specific surface area per unit area of 30 to 1000 cm²/cm².

The anchor layer having a specific surface area per unit area of 30 cm²/cm² or more, preferably 50 cm²/cm² or more can diffuse the gas generated during instantaneous evaporation of organic substances (such as a dispersant and a solvent in the ink) by irradiation of flash light to surrounding areas of the patterned thin metal lines. Such an anchor layer has a large area bonded to the patterned thin metal lines, and can effectively prevent separation of the patterned thin metal lines. The anchor layer further functions as a heat insulating layer against the heat conducted from the patterned thin metal lines to prevent damage to the bare substrate.

At a specific surface area per unit area of 1000 cm²/cm² or less, preferably 300 cm²/cm² or less, the gas diffuses smoothly to effectively prevent damage to the anchor layer, and crack of the anchor layer when a flexible bare substrate, such as a resin bare substrate, is used.

The anchor layer according to the present invention can have any transparency selected according to application. A highly transparent anchor layer is preferred because such an anchor layer can be used in a wide variety of applications, such as transparent electrodes. The anchor layer according to the present invention desirably has a total light transmittance of 70% or more, preferably 80% or more.

The anchor layer according to the present invention has a thickness of preferably 0.1 to 30 μm, more preferably 0.2 to 10 μm, most preferably 0.3 to 5 μm. At a thickness of 0.1 μm or more, the anchor layer can effectively prevent damage to the bare substrate by irradiation of flash light onto the patterned thin metal lines. At a thickness of 30 μm or less, the anchor layer can maintain proper transparency with less haze.

Any composition mainly composed of an inorganic compound can be used for the anchor layer according to the present invention. For example, a composition described in Japanese Patent Laid-open Publication No. 2007-169604 (aggregated silicon oxide particles) can preferably be used.

The aggregated silicon oxide particles are metal oxide particles having a primary particle size of 2 to 200 nm and containing 25 mass % or more aggregated particles each composed of two or more joining primary particles.

The aggregated silicon oxide particles may be composed of particulate silica alone, or may further contain titania, zirconia, and/or alumina. Such particles can form pores in the anchor layer to give absorption characteristics of the anchor layer.

The aggregated silicon oxide particles should contain 25 mass % or more aggregated particles of two or more joining primary particles relative to the total particles. Such aggregated particles contained in the anchor layer improve coating processability, can prevent crack of the anchor layer after formation of the anchor layer, and improve the absorption characteristics of the anchor layer. The content of the aggregated particles is preferably 40 mass % or more, more preferably 60 mass % or more.

The particle size of the primary particle is 2 to 200 nm, preferably 5 to 50 nm, more preferably 10 to 30 nm from the viewpoint of formation of pores and maintenance of higher transparency. A smaller number of joining primary particles is preferred. The number is usually 3 to 100 particles, preferably 5 to 50 particles, more preferably 7 to 30 particles.

The aggregated particle may have a long-chain structure of primary particles formed into a string, or may be branched and/or bent.

Such an aggregated particle can be prepared by any known method. For example, the aggregated particle can be prepared by joining primary particles of a spherical metal oxide through a metal ion having a valence of 2 or more, such as Ca²⁺, Zn²⁺, Mg²⁺, Ba²⁺, Al³⁺, and Ti⁴⁺. A silica sol string can be prepared, for example, by the method described in WO00/15552.

The content of the aggregated particle composed of two or more joining primary particles in the total particles can be adjusted by any method. The content can be adjusted simply and preferably, for example, by a method of mixing substantially 100% aggregated particles with substantially non-aggregated particles.

With the composition of the anchor layer in the present invention, the term “mainly composed of an inorganic compound” indicates that the composition is composed of 70 mass % or more, preferably 80 mass % or more, more preferably 90 mass % or more inorganic compound material relative to all the materials that form the anchor layer.

A higher rate of the inorganic compound material in the anchor layer can more effectively prevent separation of a grid (patterned thin metal lines) caused by damage to the anchor layer during thermal annealing of the patterned thin metal lines according to the present invention by irradiation of flash light.

The anchor layer according to the present invention may contain an organic compound to improve binding characteristics of the inorganic compound material in the anchor layer or binding characteristics between the anchor layer and the bare substrate, for example. In this case, the rate of the organic compound material in the anchor layer is preferably 30 mass % or less, more preferably 20 mass % or less, most preferably 10 mass % or less. The rate of the organic compound material of 30 mass % or less can reduce damage to the anchor layer during thermal annealing of the patterned thin metal lines according to the present invention by irradiation of flash light.

Any method for forming the anchor layer according to the present invention may be properly selected. A variety of application processes can be used, for example, a variety of printing processes, such as gravure printing, flexographic printing, offset printing, screen printing, and inkjet printing, and a variety of coating processes, such as roll coating, bar coating, dip coating, spin coating, casting, die coating, blade coating, curtain coating, spray coating, and doctor blade coating.

When formation of a patterned anchor layer is preferred, gravure printing, flexographic printing, offset printing, screen printing, or inkjet printing is preferably used.

The anchor layer according to the present invention can be formed by forming a film on a bare substrate by the application processes, and drying the film spontaneously or by heat, for example, by hot air or infrared radiation. The temperature for drying by heat can be properly selected according to the bare substrate to be used. For the resin film bare substrate, a typical drying temperature is preferably 200° C. or less.

Before the anchor layer according to the present invention is formed, the surface of the bare substrate or the barrier layer may be preliminarily treated with a silane coupling agent to improve adhesiveness to the bare substrate or the barrier layer.

### [Patterned Thin Metal Lines (8)]

The patterned thin metal lines according to the present invention are composed of metal nanoparticles or a metal complex. Any metal element having high conductivity can be used for the metal nanoparticles or the metal complex. For example, metals, such as gold, silver, copper, iron, nickel, and chromium, and alloys thereof can be used. From the viewpoint of conductivity and stability, silver is preferred.

The metal nanoparticle according to the present invention has an average particle size of preferably 1 nm or more and 100 nm or less, more preferably 1 nm or more and 50 nm or less, most preferably 1 nm or more and 30 nm or less.

In the present invention, the average particle size of the metal nanoparticle can be determined by observing 200 or more of exactly or substantially circular or oval metal nanoparticles at random with an electron microscope to determine the particle sizes of those metal nanoparticles, and determining the average.

Through the specification, the average particle size according to the present invention indicates the smallest distance between two parallel lines on outer edges of each exactly or substantially circular or oval metal nanoparticle observed. Images indicating side surfaces of the metal nanoparticles are not counted in the determination of the average particle size.

The metal complex according to the present invention indicates a compound composed of a ligand coordinated with metal ions as generally understood.

Any known material can be used as a metal complex for forming the patterned thin metal lines according to the present invention. For example, organic silver complexes described in Japanese Unexamined Patent Application Publication (Translation of PCT Application) No. 2008-531810 and Japanese Patent Laid-open Publication No. 2011-126861 can be preferably used.

The thin metal lines according to the present invention can be formed into any pattern, such as a stripe pattern and a mesh pattern (such as a square lattice and a honeycomb lattice). The pattern preferably has an opening rate of 80% or more from the viewpoint of transparency.

The opening rate indicates the rate of areas having no patterned thin metal lines to unit area. For example, if thin metal lines are formed in a stripe pattern having a line width of 100 μm and a line interval of 1 mm, the opening rate is 90%.

In the pattern, the line width is preferably 10 to 200 μm. A line width of 10 μm or more attains desired conductivity, and a line width of 200 μm or less attains sufficient transparency suitable for transparent electrodes.

The thin line has a height of preferably 0.1 to 5 μm. Thin lines having a height of 0.1 μm or more attain desired conductivity. Thin lines having a height of 5 μm or less can reduce influences of the difference in height on the unevenness of the thickness of a functional layer given in application to organic electronic elements.

A standard pattern of thin metal lines, such as a stripe or mesh pattern, is preferably formed by printing a desired shape with an ink containing metal nanoparticles and/or a metal complex. Such a desired shape can be printed by any known printing process, such as gravure printing, flexographic printing, offset printing, screen printing, and inkjet printing.

In this case, the ink containing metal nanoparticles and/or a metal complex permeates the porous anchor layer to form the patterned thin metal lines according to the present invention inside the anchor layer basically. For this reason, the patterned thin metal lines can be formed so as to be embedded in the anchor layer according to the present invention (see FIG. 1), or can be formed so as to be projected from the anchor layer. These states can be controlled by adjusting the heights of the patterned thin metal lines, the thickness of the anchor layer, the viscosity of the ink containing metal nanoparticles and/or a metal complex, and the porosity of the anchor layer.

### [Thermal Annealing by Irradiation of Flash Light]

In the present invention, the patterned thin metal lines containing metal nanoparticles and/or a metal complex are thermally annealed by irradiation of flash light to improve conductivity. The annealing is conducted by irradiating the patterned thin metal lines with light from a flash lamp.

The flash lamp for emitting the flash light according to the present invention can be provided with a discharge tube, such as xenon, helium, neon, and argon discharge tubes. A xenon lamp is preferably used.

The spectral range of the flash lamp in the present invention is preferably 240 to 2000 nm because such flash light does not cause damage to the bare substrate according to the present invention, such as thermal deformation.

For the conditions on irradiation with the flash lamp in the present invention, the total irradiation energy of the light is preferably 0.1 to 50 J/cm², more preferably 0.5 to 10 J/cm². The time for irradiation is preferably 10 microseconds to 100 milliseconds, more preferably 100 microseconds to 10 milliseconds. The irradiation may be performed one to multiple times. The irradiation is preferably conducted in the range of 1 to 50 times. The flash light is emitted on these preferred conditions to thermally anneal the patterned thin metal lines without damage to the bare substrate, attaining a highly conductive substrate.

The bare substrate is irradiated with flash light by a flash lamp preferably from the printed surface with the patterned thin metal lines. A transparent bare substrate can be irradiated with flash light from one or both of the surfaces of the bare substrate.

The irradiation of flash light may be conducted in air in the present invention, or in an atmosphere of an inert gas, such as nitrogen, argon, and helium.

The temperature of the bare substrate during the irradiation of flash light can be determined according to thermal properties, such as the heat-resisting temperature of the bare substrate, the boiling point (vapor pressure) of a dispersive medium for the ink containing metal nanoparticles and/or a metal complex, the type and pressure of the atmosphere gas, and the dispersibility and oxidation properties of the ink. The irradiation of flash light is preferably conducted at room temperature or more and 200° C. or less. Before the irradiation of flash light, a bare substrate provided with the patterned thin metal lines may be preliminarily heat-treated.

Any irradiating apparatus for the flash lamp satisfying the irradiation energy and the time for irradiation can be used.

### [Barrier Layer (4)]

A small amount of moisture or oxygen existing in an organic electronic element, such as an organic EL element, readily degrades the performance of the element. A barrier layer having a high barrier function against moisture or oxygen provided on the resin bare substrate can effectively prevent the diffusion of moisture or oxygen through the resin bare substrate into the element.

The barrier layer according to the present invention may have any composition and any structure and may be formed by any method. For example, a barrier layer can be formed with an inorganic compound, such as silica, by vacuum deposition or chemical vapor deposition (CVD). The barrier layer can also be formed by applying a coating solution containing a polysilazane compound, drying the coating solution, and oxidizing the coating by irradiation with ultraviolet light under a nitrogen atmosphere containing oxygen and water vapor.

The coating solution containing the polysilazane compound can be properly applied by any process. Specific examples of the process include spin coating, roll coating, flow coating, an inkjet process, spray coating, a print process, dip coating, a casting film forming process, bar coating, and gravure printing.

The coating solution containing the polysilazane compound can be applied by any coating or printing process. Examples of such a coating process include roll coating, bar coating, dip coating, spin coating, casting, die coating, blade coating, curtain coating, spray coating, and doctor blade coating, and examples of such a printing process include gravure printing, flexographic printing, offset printing, screen printing, and inkjet printing.

If a patterned barrier layer is preferred, gravure printing, flexographic printing, offset printing, screen printing, or inkjet printing is preferably used.

The polysilazane used in the present invention is a polymer having a silicon-nitrogen bond, and is an inorganic polymer as a ceramic precursor, having Si—N, Si—H and/or N—H, for SiO₂, Si₃N₄ and an intermediate solid solution SiOₓN_{y} between SiO₂ and Si₃N₄.

A polysilazane compound described in Japanese Patent Laid-open Publication No. 8-112879 can preferably be used in the resin bare substrate. The compound is converted into a ceramic, i.e., silica at a relatively low temperate, and is represented by Formula (1):

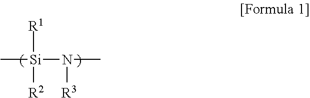

where R¹, R², and R³ each represent a hydrogen atom or an alkyl, alkenyl, cycloalkyl, aryl, alkylsilyl, alkylamino, or alkoxy group.

All of R¹, R², and R³ are hydrogen atoms in perhydropolysilazane whereas one of R¹, R², and R³ is an alkyl, alkenyl, cycloalkyl, aryl, alkylsilyl, alkylamino, or alkoxy group in organopolysilazane. Perhydropolysilazane (where R¹, R², and R³ are all hydrogen atoms) is particularly preferred because a dense barrier film can be formed.

The barrier layer according to the present invention may have a single-layer configuration or may have a multilayer configuration composed of two or more sublayers. The barrier layer having a multilayer configuration may be composed of sublayers of inorganic compounds, or may be composed of hybrid sublayers of at least one inorganic compound and at least one organic compound. The laminate structure of the barrier layer may include a stress relaxing sublayer.

In both the single-layer and multilayer configurations, the entire barrier layer has a total thickness of preferably 30 to 1000 nm, more preferably 30 to 500 nm, particularly preferably 90 to 500 nm. At a thickness of 30 nm or more, the barrier layer has a uniform thickness to attain high barrier performance. At a thickness of 1000 nm or less, crack caused by bending the bare substrate is significantly reduced, and an increase in internal stress does not occur during film formation, preventing generation of defects.

The barrier layer according to the present invention has the following barrier characteristics. The water vapor permeation rate (at 25±0.5° C. and relative humidity: 90±2% RH) determined by the method in accordance with JIS K 7129-1992 is preferably 1×10⁻³ g/(m²·24 h) or less. The oxygen transmission rate determined by the method in accordance with JIS K 7126-1987 is preferably 1×10⁻³ ml/m²·24 h·atm or less (1 atm is equal to 1.01325×10⁵ Pa), and the water vapor transmission rate (25±0.5° C., relative humidity: 90±2% RH) determined in the same manner is preferably 1×10⁻³ g/(m²·24 h) or less.

Before the barrier layer according to the present invention is formed, the surface of the bare substrate may be preliminarily treated with a silane coupling agent to improve adhesiveness of the bare substrate.

The barrier layer can be eliminated even in the resin bare substrate.

[Conductive Polymer Layer (10)]

The conductive polymer layer according to the present invention is composed of a conductive polymer at least containing a n-conjugated conductive polymer and polyanion.

The conductive polymer layer according to the present invention may contain a water-soluble organic compound as a second dopant, a resin component as a binder material, and a variety of additives as a coating aid.

The dry thickness of the conductive polymer layer is preferably 30 to 2000 nm. The dry thickness is more preferably 100 nm or more from the viewpoint of conductivity, and most preferably 300 nm or more from the viewpoint of a reduction in the difference in the heights of the patterned thin metal lines according to the present invention to reduce influences on the unevenness of the thickness of a functional layer when the conductive substrate according to the present invention is used in organic electronic elements. The dry thickness is more preferably 1000 nm or less, and most preferably 800 nm or less from the viewpoint of transparency.

The conductive polymer layer according to the present invention can be formed so as to be embedded in the anchor layer according to the present invention, or may be formed so as to cover the anchor layer. These states can be controlled by adjusting the thickness of the conductive polymer layer, the thickness of the anchor layer, the viscosity of a solution for forming a conductive polymer layer, and the porosity of the anchor layer. When the conductive substrate according to the present invention is used as an electrode for an organic electronic element, the conductive polymer layer covering the anchor layer is preferred because a smooth surface of an electrode can be obtained.

The conductive polymer layer can be formed by any appropriate application process selected from, for example, a variety of printing processes, such as gravure printing, flexographic printing, offset printing, screen printing, and inkjet printing, and a variety of coating processes, such as roll coating, bar coating, dip coating, spin coating, casting, die coating, blade coating, curtain coating, spray coating, and doctor blade coating.

A patterned anchor layer, if preferred, can be formed by gravure printing, flexographic printing, offset printing, screen printing, or inkjet printing.

The conductive polymer layer according to the present invention can be formed by applying a solution of a conductive polymer containing at least a n-conjugated conductive polymer and polyanion onto the substrate by the application processes to form a film, and drying the film spontaneously or by heat, for example, by hot air and infrared radiation.

The temperature for drying by heat can be properly selected according to the characteristics of the bare substrate to be used. For the resin film bare substrate, a typical drying temperature is preferably 200° C. or less.

In drying with infrared radiation, to selectively heat the conductive polymer layer, an infrared wavelength region barely absorbed by the bare substrate is preferably selected. For example, near-infrared radiation up to 1500 nm is suitable for a bare substrate of a PET or PEN film. Alternatively, an infrared wavelength region near 3 μm around which water has the absorption maximum is preferred for rapid heat drying.

### (1) Conductive Polymer

The conductive polymer according to the present invention comprises a n-conjugated conductive polymer and polyanion. Such a conductive polymer can be readily prepared by chemical oxidative polymerization of a precursor monomer for preparing a n-conjugated conductive polymer described later in the presence of a proper oxidizing agent, an oxidation catalyst, and a polyanion described later.

(1.1) n-Conjugated Conductive Polymer

Any n-conjugated conductive polymer can be used in the present invention. Example of such a usable polymer include chain conductive polymers, such as polythiophenes (including unsubstituted polythiophene, hereinafter the same holds), polypyrroles, polyindoles, polycarbazoles, polyanilines, polyacetylenes, polyfurans, polyparaphenylene vinylenes, polyazulenes, polyparaphenylenes, polyparaphenylene sulfides, polyisothianaphthenes, and polythiazyls. Among these, preferred are polythiophenes and polyanilines from the viewpoint of conductivity, transparency, stability, and adsorption to metal nanoparticles. Polyethylenedioxythiophene is most preferred.

The precursor monomer used in preparation of the n-conjugated conductive polymer has a n-conjugated structure in the molecule. When the precursor monomer is polymerized by action of a proper oxidizing agent, a n-conjugated structure is also formed in the main chain of the resulting polymer. Examples of the precursor monomer include pyrrole and derivatives thereof, thiophene and derivatives thereof, and aniline and derivatives thereof.

### (1.2) Polyanion

The polyanion used in the present invention is an acidic polymer in the form of a free acid, and is a polymer of a monomer unit having an anionic group or a copolymer of a monomer unit having an anionic group and another monomer unit having no anionic group. The free acid may be a partially neutralized salt. The polyanion includes substituted or unsubstituted polyalkylenes, substituted or unsubstituted polyalkenylenes, substituted or unsubstituted polyimides, substituted or unsubstituted polyamides, substituted or unsubstituted polyesters, and copolymers thereof which have at least anionic groups.

The polyanion can facilitate dissolution of the n-conjugated conductive polymer in a solvent. The anionic group of the polyanion functions as a dopant to the n-conjugated conductive polymer to improve the conductivity and heat resistance of the n-conjugated conductive polymer.

The anionic group of the polyanion may be any functional group that can dope the n-conjugated conductive polymer by chemical oxidation. Among these, preferred are monosubstituted sulfate ester groups, monosubstituted phosphate ester groups, a phosphate group, a carboxy group, and a sulfo group from the viewpoint of ease of production and stability. More preferred are a sulfo group, a monosubstituted sulfate group, and a carboxy group from the viewpoint of the doping effect of the functional group on the n-conjugated conductive polymer.

Specific examples of the polyanion include polyvinylsulfonic acid, polystyrene sulfonic acid, polyallylsulfonic acid, polyacrylic ethylsulfonic acid, polyacrylic butylsulfonic acid, poly-2-acrylamide-2-methylpropanesulfonic acid, polyisoprenesulfonic acid, polyvinylcarboxylic acid, polystyrenecarboxylic acid, polyallylcarboxylic acid, polyacrylic carboxylic acid, polymethacrylic carboxylic acid, poly-2-acrylamide-2-methylpropanecarboxylic acid, polyisoprenecarboxylic acid, and polyacrylic acid. The polyanion may be a homopolymer thereof or a copolymer thereof.

The polyanion may have a fluorine atom (F) in the compound. Specific examples thereof include Nafion having perfluorosulfonate groups (available from E. I. du Pont de Nemours and Company), and FLEMION comprising perfluorovinyl ether having carboxylate groups (available form ASAHI GLASS CO., LTD.).

The mass ratio of the n-conjugated conductive polymer to the polyanion contained in the conductive polymer “n-conjugated conductive polymer”: “polyanion” is preferably 1:1 to 20. The mass ratio is more preferably within the range of 1:2 to 10 from the viewpoint of conductivity and dispersibility.

Such a conductive polymer is commercially available, and can be preferably used in the present invention. For example, conductive polymers composed of poly(3,4-ethylenedioxythiophene) and polystyrenesulfonic acid (abbreviated to PEDOT-PSS) are commercially available from Heraeus Holding GmbH under the trade names Clevios series, from Sigma-Aldrich, Inc. under the trade names PEDOT-PSS 483095 and 560596, and from Nagase Chemtex Corporation under the trade names Denatron series. Polyaniline is commercially available from Nissan Chemical Industries, Ltd. under the trade names ORMECON series.

### (2) Second Dopant

Any known water-soluble organic compound can be appropriately used in the present invention. Suitable examples thereof include oxygen-containing compounds. Examples of the oxygen-containing compound include hydroxyl-containing compounds, carbonyl-containing compounds, ether-containing compounds, and sulfoxide-containing compounds. Examples of the hydroxyl-containing compound include ethylene glycol, diethylene glycol, propylene glycol, trimethylene glycol, 1,4-butanediol, and glycerol. Among these, preferred are ethylene glycol and diethylene glycol. Examples of the carbonyl-containing compound include isophorone, propylene carbonate, cyclohexanone, and γ-butyrolactone. Examples of the ether-containing compound include diethylene glycol monoethyl ether. Examples of the sulfoxide-containing compound include dimethyl sulfoxide. These may be used alone or in combination. Use of at least one selected from dimethyl sulfoxide, ethylene glycol, and diethylene glycol is preferred.

(3) Resin component

The conductive polymer layer according to the present invention comprises the conductive polymer comprising at least a n-conjugated conductive polymer and polyanion, and may further contain a transparent resin component and additives to attain desirable film forming properties and strength of the film.

The transparent resin component can be any transparent resin component compatible with or dispersible in the conductive polymer after a mixing process. The transparent resin component may be a thermosetting resin or a thermoplastic resin.

Examples thereof include polyester resins, e.g., polyethylene terephthalate), poly(butylene terephthalate), and poly(ethylene naphthalate); polyimide resins, e.g., polyimides and poly(amide-imide)s; polyamide resins, e.g., polyamide 6, polyamide 6,6, polyamide 12, and polyamide 11; fluorinated resins, e.g., polyvinylidene fluoride, polyvinyl fluoride, polytetrafluoroethylene, ethylene tetrafluoroethylene copolymers, and polychlorotrifluoroethylene; vinyl resins, e.g., poly(vinyl alcohol), polyvinyl ethers, poly(vinyl butyral), poly(vinyl acetate), and poly(vinyl chloride); epoxy resins; xylene resins; aramide resins; polyurethane resins; polyurea resins; melamine resins; phenol resins; polyether resins; acrylic resins; and copolymers thereof.

The transparent resin component is preferably compounded with a binder resin homogeneously dispersible in an aqueous solvent or a water-soluble binder resin because the conductive substrate has high surface smoothness, in addition to high transparency and conductivity.

### (3.1) Binder Resin Homogeneously Dispersible in Aqueous Solvent

The binder resin homogeneously dispersible in an aqueous solvent indicates that colloidal particles of the binder resin can be homogeneously dispersed in an aqueous solvent without aggregation. Colloidal particles typically have a size of about 0.001 to 1 μm (1 to 1000 μm).

The colloidal particles can be determined with a light scattering photometer.

The aqueous solvent indicates not only pure water (including distilled water and deionized water) but also aqueous solution containing acid, alkali, or salt, hydrous organic solvent, and hydrophilic organic solvent. Examples thereof include pure water (including distilled water and deionized water), alcohols, such as methanol and ethanol, and mixtures of water and alcohols.

The binder resin homogeneously dispersible in an aqueous solvent according to the present invention is preferably transparent.

The binder resin homogeneously dispersible in an aqueous solvent according to the present invention can be any medium that can form a film. Examples of the binder resin homogeneously dispersible in an aqueous solvent include acrylic resin emulsions, aqueous urethane resins, and aqueous polyester resins.

The acrylic resin emulsion is composed of a polymer of vinyl acetate, acrylic acid, or acrylic acid-styrene or a copolymer thereof with a different monomer. The acrylic resin emulsions are categorized into anionic emulsions having acid sites forming salt with lithium, sodium, potassium, or ammonium and cationic emulsions composed of a copolymer having a nitrogen atom forming a hydrochloric acid salt. Anionic emulsions are preferred.

Examples of the aqueous urethane resin include water-dispersible urethane resins and aqueous ionomeric urethane resins (anionic). Examples of the water-dispersible urethane resins include polyether urethane resins and polyester urethane resins. Preferred are polyester urethane resins.

Examples of the aqueous ionomeric urethane resins include polyester urethane resins, polyether urethane resins, and polycarbonate urethane resins. Preferred are polyester urethane resins and polyether urethane resins.

Aqueous polyester resins are prepared from polybasic acid components and polyol components.

Examples of the polybasic acid component include terephthalic acid, isophthalic acid, phthalic acid, naphthalenedicarboxylic acid, adipic acid, succinic acid, sebacic acid, and dodecanedioic acid. These may be used alone or in combination. Particularly preferred polybasic acid components are terephthalic acid and isophthalic acid, which are produced on an industrial scale at low cost.

Typical examples of the polyol component include ethylene glycol, propylene glycol, 1,4-butanediol, 1,6-hexanediol, neopentyl glycol, diethylene glycol, dipropylene glycol, cyclohexane dimethanol, and bisphenol. These may be used alone or in combination. Particularly preferred polyol components are ethylene glycol, propylene glycol, and neopentyl glycol, which are produced on an industrial scale at low cost and improve the compatibility between several characteristics such as solvent-resistance and weather resistance of a resin coating film.

These binder resins homogeneously dispersible in an aqueous solvent may be used alone or in combination.

The amount of the polymer dispersible in an aqueous solvent is preferably 50 to 1000 mass %, more preferably 100 to 900 mass %, most preferably 200 to 800 mass % relative to the conductive polymer from the viewpoint of transparency and conductivity.

### (3.2) Water-Soluble Binder Resin

The water-soluble binder resin preferably includes a structural unit represented by Formula (2):

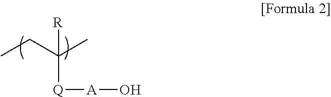

where R represents a hydrogen atom or a methyl group; Q represents —C(═O)O— or —C(═O)NRa—; Ra represents a hydrogen atom or an alkyl group; A represents a substituted or unsubstituted alkylene group or —(CH₂CHRbO)ₓCH₂CHRb— (where Rb represents a hydrogen atom or an alkyl group, and x represents the average number of repeating units).

Such a water-soluble binder resin is highly compatible with the conductive polymer. Since the resin also has the same advantageous effects as those of the second dopant, the use of the resin can contribute to an increase in the thickness of the conductive polymer layer without reductions in conductivity and transparency.

The water-soluble binder resin indicates a binder resin that can be dissolved in an amount of 0.001 g or more in 100 g of water at 25° C. The dissolution can be measured with a haze meter or turbidity meter.

The water-soluble binder resin is preferably transparent.

The water-soluble binder resin has a structure containing a structural unit represented by Formula (2). The water-soluble binder resin may be a homopolymer represented by Formula (2) or a copolymer with another monomer component. The water-soluble binder resin copolymerized with another monomer component includes the structural unit represented by Formula (2) in a proportion of preferably 10 mol % or more, more preferably 30 mol % or more, most preferably 50 mol % or more.

The water-soluble binder resin is contained in the conductive polymer layer in a content of preferably 40 mass % or more and 95 mass % or less, more preferably 50 mass % or more and 90 mass % or less.

In the present invention, the water-soluble binder resin has a number average molecular weight of preferably 3000 to 2000000, more preferably 4000 to 500000, most preferably 5000 to 100000.

In the present invention, the number average molecular weight and the molecular weight distribution of the water-soluble binder resin can be determined by well-known gel permeation chromatography (GPC). Any solvent that can dissolve the binder resin may be used. The solvent is preferably tetrahydrofuran (THF), dimethylformamide (DMF), and CH₂Cl₂, more preferably THF and DMF, most preferably DMF. The measurement can be conducted at any temperature. The temperature is preferably 40° C.

### [Organic Electronic Element (20)]

The organic electronic element according to the present invention includes a conductive substrate prepared by the method according to the present invention and an organic functional layer.

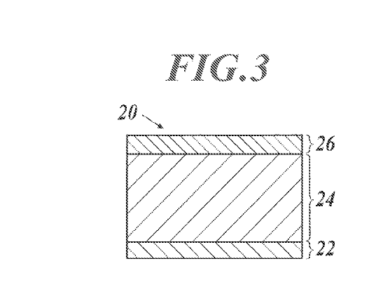

An organic electronic element 20 can be prepared by the following method, for example. As shown in FIG. 3, an organic functional layer 24 is formed on a transparent conductive substrate prepared by the method according to the present invention functioning as a first electrode 22, and then a second electrode 26 is formed on the organic functional layer 24 opposite to the first electrode 22.

Examples of the organic functional layer 24 include organic luminous layers, organic photoelectric layers, and liquid crystal polymer layers. In the present invention, the organic functional layer 24 is particularly effective when the functional layer is a thin, current-driven organic luminous layer or organic photoelectric layer.

Components of an organic EL element and an organic photoelectric element, which are organic electronic elements according to the present invention, will now be described.

### (1) Organic EL Element

### (1.1) Configuration of Organic Functional Layer (Organic Luminous Layer)

In the present invention, an organic EL element including an organic luminous layer as an organic functional layer may further include a layer for controlling light emission, such as a hole injecting layer, a hole transporting layer, an electron transporting layer, an electron injecting layer, a hole blocking layer, and an electron blocking layer.

The conductive polymer layer according to the present invention disposed on a transparent electrode can also function as a hole injecting layer. Alternatively, an independent hole injecting layer may be disposed.

Specific, but non-limiting examples of a preferred configuration will be shown:

(i) (First electrode)/luminous layer/electron transporting layer/(second electrode)
(ii) (First electrode)/hole transporting layer/luminous layer/electron transporting layer/(second electrode)
(iii) (First electrode)/hole transporting layer/luminous layer/hole blocking layer/electron transporting layer/(second electrode)
(iv) (First electrode)/hole transporting layer/luminous layer/hole blocking layer/electron transporting layer/cathode buffer layer/(second electrode)
(v) (First electrode)/anode buffer layer/hole transporting layer/luminous layer/hole blocking layer/electron transporting layer/cathode buffer layer/(second electrode)

The luminous layer may be composed of one of the monochromatic luminous layers having the maximum luminescent wavelengths of 430 to 480 nm, 510 to 550 nm, and 600 to 640 nm, respectively. Alternatively, at least these three luminous layers may be laminated into a white luminous layer. A non-luminous intermediate layer may be disposed between luminous layers. The organic EL element according to the present invention preferably includes a white luminous layer.

Examples of a luminous material or a doping material usable in the organic luminous layer in the present invention include, but should not be limited to, anthracene, naphthalene, pyrene, tetracene, coronene, perylene, phthaloperylene, naphthaloperylene, diphenylbutadiene, tetraphenylbutadiene, coumarin, oxadiazole, bisbenzoxazoline, bisstyryl, cyclopentadiene, quinoline metal complexes, tris(8-hydroxyquinolinato)aluminum complexes, tris(4-methyl-8-quinolinato)aluminum complexes, tris(5-phenyl-8-quinolinato)aluminum complexes, aminoquinoline metal complexes, benzoquinoline metal complexes, tri-(p-terphenyl-4-yl)amine, 1-aryl-2,5-di(2-thienyl)pyrrole derivatives, pyran, quinacridone, rubrene, distyrylbenzene derivatives, distyrylarylene derivatives, and a variety of fluorescence dyes, rare earth metal complexes, and phosphorescence luminous materials. Preferably, 90 to 99.5 parts by mass of luminous material selected from these compounds and 0.5 to 10 parts by mass of doping material selected from these compounds are contained.

The organic luminous layer is prepared from the material by a known process. Examples of the process include deposition, coating, and transfer.

### (1.2) Electrode

The conductive substrate according to the present invention is used as a first electrode or a second electrode. Preferably, the transparent conductive substrate according to the present invention functions as a first electrode, more specifically an anode.

The second electrode may be composed of a single layer of a conductive material, or may be composed of a conductive material and a resin for holding the conductive material. The conductive material for the second electrode is an electrode substance, such as metals having small work functions of 4 eV or less (referred to as an electron-injecting metal), alloys, electrically conductive compounds, and mixtures thereof.

Specific examples of such an electrode substance include sodium, sodium-potassium alloys, magnesium, lithium, magnesium/copper mixtures, magnesium/silver mixtures, magnesium/aluminum mixtures, magnesium/indium mixtures, aluminum/aluminum oxide (Al₂O₃) mixtures, indium, lithium/aluminum mixtures, and rare earth metals.

Among these, preferred is a mixture of an electron-injecting metal and a second stable metal having a work function larger than that of the electron-injecting metal, such as a magnesium/silver mixture, a magnesium/aluminum mixture, a magnesium/indium mixture, an aluminum/aluminum oxide (Al₂O₃) mixture, a lithium/aluminum mixture, or elemental aluminum, from the viewpoint of electron injection ability and oxidation resistance. A cathode can be prepared by forming a thin film of the electrode substance by deposition or sputtering. The cathode preferably has a sheet resistance of several hundreds of ohms per square or less, and a thickness of usually 10 nm to 5 μm, preferably 50 to 200 nm.

Such a metal material used as the conductive material for the second electrode reflects the light incident on the second electrode to the first electrode. The metal conductive material for the second electrode enables reuse of the light to improve the light extraction efficiency.

### (2) Organic Photoelectric Element

The organic photoelectric element preferably has a laminate structure of a first electrode, a photoelectric layer having a bulk heterojunction structure (composed of a p-type semiconductive sublayer and an n-type semiconductive sublayer) (hereinafter also referred to as a bulk heterojunction layer), and a second electrode.

The transparent electrode according to the present invention is disposed at least on an incident light side.

An intermediate layer, such as an electron transporting layer, may be disposed between the photoelectric layer and the second electrode.

### (2.1) Photoelectric Layer

The photoelectric layer converts light energy into electrical energy, and preferably is composed of a bulk heterojunction layer of a homogeneous mixture of a p-type semiconductive material and an n-type semiconductive material. The p-type semiconductive material relatively functions as an electron donor while the n-type semiconductive material relatively functions as an electron acceptor.

The electron donor and the electron acceptor indicate “substances that allow electrons to move from one of the substances to the other in response to absorption of light to form pairs of holes and electrons (charge separation).” Unlike electrodes which simply give or receive electrons, these substances donate or accept electrons by photoreaction.

Examples of the p-type semiconductive material include a variety of condensed polycyclic aromatic compounds and conjugated compounds.

Examples of condensed polycyclic aromatic compounds include compounds, such as anthracene, tetracene, pentacene, hexacene, heptacene, chrysene, picene, fulminene, pyrene, peropyrene, perylene, terrylene, quaterrylene, coronene, ovalene, circumanthracene, bisantene, zethrene, heptazethrene, pyranthrene, violanthrene, isoviolanthrene, circobiphenyl, and anthradithiophene, and derivatives and precursors thereof.

Examples of conjugated compounds include polythiophene and oligomers thereof, polypyrrole and oligomers thereof, polyaniline, polyphenylene and oligomers thereof, polyphenylene vinylene and oligomers thereof, polythienylene vinylene and oligomers thereof, polyacetylene, polydiacetylene, tetrathiafulvalene compounds, quinone compounds, cyano compounds such as tetracyanoquinodimethane, fullerene, and derivatives or mixtures thereof.

Among polythiophene and oligomers thereof, preferred are thiophene hexamers, such as α-sexithiophene, α,ω-dihexyl-α-sexithiophene, α,ω-dihexyl-α-quinquethiophene, α,ω-bis(3-butoxypropyl)-α-sexithiophene.

Examples of other p-type semiconductive polymers include polyacetylene, poly(para-phenylene), polypyrrole, poly(para-phenylene sulfide), polythiophene, polyphenylene vinylene), polycarbazole, polyisothianaphthene, polyheptadiyne, polyquinoline, and polyaniline. Further examples thereof include alternate copolymers of substituted and unsubstituted polythiophenes described in Japanese Patent Laid-open Publication No. 2006-36755; polymers having fused thiophene ring structures described in Japanese Patent Laid-open Publication Nos. 2007-51289 and 2005-76030, J. Amer. Chem. Soc., 2007, p. 4112, and J. Amer. Chem. Soc., 2007, p. 7246; and thiophene copolymers described in WO2008/000664, Adv. Mater., 2007, p. 4160, and Macromolecules, 2007, Vol. 40, p. 1981.

Organic molecular complexes, such as porphyrin and copper phthalocyanine complex, tetrathiafulvalene (TTF)-tetracyanoquinodimethane (TCNQ) complex, bis(ethylene)dithiotetrathiafulvalene (BEDTTTF)-perchloric acid complex, BEDTTTF-iodine complex, and TCNQ-iodine complex; fullerenes C60, C70, C76, C78, and C84; carbon nanotubes, such as single-walled nanotubes (SWNT); dyes, such as merocyanine dyes and hemicyanine dyes; o-conjugated polymers composed of polysilanes and polygermanes; and the mixture of organic and inorganic materials described in Japanese Patent Laid-open Publication No. 2000-260999 can also be used.

Among these n-conjugated materials, preferred is at least one selected from the group consisting of condensed polycyclic aromatic compounds, such as pentacene, fullerenes, condensed cyclic tetracarboxdiimides, metal phthalocyanine, and metal porphyrin. More preferred is pentacene.

Examples of pentacene include pentacene derivatives having substituents described in WO03/16599, WO03/28125, U.S. Pat. No. 6,690,029, and Japanese Patent Laid-open Publication No. 2004-107216; pentacene precursors described in U.S. Patent Application Publication No. 2003/136964 and others; substituted acenes and derivatives thereof described in J. Amer. Chem. Soc., vol. 127, No. 14, 4986.

Among these compounds, preferred are compounds which have high solubility in organic solvents so as to allow a solution process, can form crystalline thin films after drying, and can attain high mobility. Examples of such compounds include acene compounds replaced with trialkylsilylethynyl groups described in J. Amer. Chem. Soc., vol. 123, p. 9482, and J. Amer. Chem. Soc., vol. 130 (2008), No. 9, 2706; and precursors, such as the pentacene precursor described in U.S. Patent Application Publication No. 2003/136964 and the porphyrin precursor described in Japanese Patent Laid-open Publication No. 2007-224019.

Among these, preferred are the precursors. The precursors become insoluble after conversion. For this reason, the bulk heterojunction layer composed of such a precursor does not dissolve during formation of a hole transporting layer, an electron transporting layer, an hole blocking layer, or an electron blocking layer on the bulk heterojunction layer by the solution process, preventing mixing of the material constituting the formed layer with the material constituting the bulk heterojunction layer. Such a bulk heterojunction layer can attain high efficiency and long life.

Preferred p-type semiconductive materials are converted from p-type semiconductive material precursors by exposure to heat, light, radiation, or vapor of a compound causing chemical reaction to cause change in the chemical structures. Among these, preferred p-type semiconductive material precursors are compounds that cause chemical structural change by heat.

Examples of the n-type semiconductive material include fullerene, octaazaporphyrin, perfluoro derivatives of p-type semiconductors (such as perfluoropentacene and perfluorophthalocyanine), and high-molecular compounds having skeletons of aromatic carboxylic anhydrides or imides, such as naphthalenetetracarboxylic anhydride, naphthalenetetracarboxdiimide, perylenetetracarboxylic anhydride, and perylenetetracarboxdiimide.

Among these, preferred are fullerene-containing high-molecular compounds. Examples of fullerene-containing high-molecular compounds include high-molecular compounds having skeletons of fullerenes C60, C70, C76, C78, C84, C240, and C540, mixed fullerenes, fullerene nanotubes, multi-walled nanotubes, single-walled nanotubes, and nanohorns (conical). Among these, preferred are high-molecular compounds (derivatives) having skeletons of fullerene C60.

Fullerene-containing polymers are categorized into polymers containing fullerene as a pendant group bonded to the main chain and polymers containing fullerene in the main chain. Preferred are polymers containing fullerene in the main chain.

The polymers containing fullerene in the main chain have no branched structure. For this reason, these polymers, after solidified, can be packed highly densely to attain high mobility of carriers.

Examples of a process of forming a bulk heterojunction layer composed of an electron acceptor and an electron donor include deposition and coating processes (including casting and spin coating).

The photoelectric element according to the present invention may be used in the form of a single layer or a laminate (tandem structure) in photoelectric devices such as solar cells.

The photoelectric devices are preferably sealed by a known method to avoid deterioration by oxygen and moisture in environments.

The present invention will now be described in further detail according to non-limiting Examples. In Examples, “%” represents and “mass %,” unless otherwise specified.

### Example 1

### Preparation of Transparent Conductive Substrate ACF-1

### (Formation of Patterned Thin Metal Lines)

A polyethylene terephthalate (PET) film (thickness: 110 μm, dimensions: 180 by 180 mm) provided with hard coat layers on both surfaces thereof was prepared. A pattern of thin metal lines was printed on one surface of the film by gravure printing with a silver nanoparticle ink (TEC-PR-030; available from InkTec Co., Ltd.). The printing was conducted through a gravure printing pattern of a square lattice having a width of 30 μm and a pitch of 0.75 mm such that the average height of the thin lines became 0.8 μm after annealing. A compact thick-film semi-automatic printing machine STF-1501P (available from Tokai Shoji Co., Ltd.) was used. The pattern was printed in an area of 150 square millimeters.

### (Annealing of Patterned Thin Metal Lines)

After printing of the pattern of thin metal lines, the patterned thin metal lines were annealed on a hot plate at 120° C. for 30 minutes to prepare Transparent conductive substrate ACF-1.

<Preparation of Transparent Conductive Substrate ACF-2>

Transparent conductive substrate ACF-2 was prepared as in ACF-1 except that the patterned thin metal lines were annealed by the following method.

### (Annealing of Patterned Thin Metal Lines)

After printing of the pattern of thin metal lines, the printed surface having the patterned thin metal lines was irradiated once for 2 milliseconds with a flash light having an irradiation energy of 2.5 J/cm² emitted from a xenon flash lamp 2400WS (available from COMET Corp.) equipped with a short wavelength (250 nm or less) cutting filter, so that the thermal annealing is performed.

### <Preparation of Transparent Conductive Substrate ACF-3>

### (Formation of Anchor Layer)

A polyethylene terephthalate (PET) film (thickness: 110 μm, dimensions: 180 by 180 mm) provided with hard coat layers on both surfaces thereof was prepared. A porous anchor layer containing 90 mass % of an inorganic compound was formed with reference to Examples 2 and 10 (Paragraphs 0065 and 0078) described in Japanese Patent Laid-open Publication No. 2007-169604, such that the average dry thickness was 0.8 μm.

Specifically, “Dispersion” containing aggregated silicon oxide particles was prepared. “Dispersion” was prepared by the following method (the same dispersion containing aggregated silicon oxide particles was used in subsequent Examples).

Glycidoxypropyltrimethoxysilane (306.84 g) and titanium tetraisopropoxide (266.87 g) were dissolved in ethyl cellosolve (257.26 g). A mixed solution of concentrated nitric acid (100.68 g), water (31.61 g), and ethyl cellosolve (36.75 g) was added dropwise to the solution. The resulting solution was allowed to stand at 30° C. for four hours for reaction to prepare “Binder solution” having a solid concentration of 30 mass %.

Cyclohexanone (620 g), and then Binder solution (20 g) was sequentially added dropwise to “Dispersion” (360 g) with stirring. The resulting solution was stirred at room temperature for one hour to prepare “Coating solution” having a solid concentration of 6 mass %.

A polyethylene terephthalate (PET) film (thickness: 110 μm, dimensions: 180 by 180 mm) provided with hard coat layers on both surfaces thereof was prepared. The coating solution was applied onto one of the surfaces of the film by bar coating such that the average dry thickness was 0.8 μm. The film was heated at 120° C. for one minute, and was aged at 60° C. for 3 days to form a porous anchor layer composed of 90 mass % of an inorganic compound.

### (Preparation of Dispersion Liquid)

Pure water was added to commercially available liquid glass JIS No. 3 (SiO₂/Na₂O, molar ratio: 3.22, SiO₂ content: 28.5 wt %) to prepare an aqueous sodium silicate solution (SiO₂ content: 3.6 wt %). The sodium silicate aqueous solution was passed through a column filled with a cationic exchange resin (trade name: Amberlite 120B) to prepare an aqueous colloidal solution of active silicic acid having an SiO₂ content of 3.60 wt %, a pH of 2.90, and an electric conductivity of 580 μS/cm.

The aqueous colloidal solution of active silicic acid (888 g) (SiO₂: 32.0 g) was placed in a glass container, and pure water (600 g) was added under stirring to prepare an aqueous colloidal solution of active silicic acid having an SiO₂ content of 2.15 wt % and a pH of 3.07. To this solution, 10 wt % calcium nitrate aqueous solution (pH: 4.32, amount: 59 g, amount of CaO: 2.02 g) was added at room temperature under stirring. The solution was further stirred for 30 minutes. Calcium nitrate was added in an amount in terms of CaO of 6.30 wt % relative to SiO₂.

An acidic sol of spherical silica having an average particle size D2 (determined by a nitrogen adsorption method) of 20.5 nm was prepared. The acidic sol available from Nissan Chemical Industries, Ltd. under the trade name SNOWTEX 0-40 (specific gravity: 1.289, viscosity: 4.10 mPa·s, pH: 2.67, electric conductivity: 942 μS/cm, SiO₂ content: 40.1 wt %) was placed to another glass container in an amount of 2000 g (SiO₂ amount: 802 g). To this silica sol, 5 wt % aqueous sodium hydroxide solution (6.0 g) was added dropwise under stirring. The mixture was further stirred for 30 minutes to prepare an acidic silica sol having a pH of 4.73 and an SiO₂ content of 40.0 wt %.

The particle size (D1) of the silica sol determined by dynamic light scattering was 35.0 nm, and the ratio D1/D2 was 1.71. The silica sol was observed with an electron microscope to find spherical silica colloidal particles almost monodispersed. Neither bonding nor aggregation of these colloidal particles was found.

The acidic sol of spherical silica having an average particle size of 20.5 nm was added to the aqueous colloidal solution of active silicic acid containing calcium nitrate [Mixed solution (a)] under stirring. The mixture was further stirred for 30 minutes to prepare Mixed solution (b). In Mixed solution (b), the weight ratio A/B of the amount of silica (A) derived from the acidic sol of spherical silica to the amount of silica (B) derived from the aqueous colloidal solution of active silicic acid [Mixed solution (a)] was 25.1, the pH was 3.60, and the electric conductivity was 2580 μS/cm. The total content of silica (A+B) in Mixed solution (b) was 23.5 wt % in terms of the SiO₂ content. The content of calcium ion in the solution was 0.242 wt % relative to SiO₂ in terms of CaO.

To Mixed solution (b), 1.97 wt % aqueous sodium hydroxide solution (330 g) was added over 10 minutes under stirring. The solution was further stirred for one hour to prepare Mixed solution (c). Mixed solution (c) had a pH of 9.22, an electric conductivity of 3266 μS/cm, an SiO₂ content of 21.5 wt %, and a molar ratio SiO₂/Na₂O of 163.5. Mixed solution (c) contained a small amount of silica gel.

Alkaline Mixed solution (c) (1800 g) was placed in an autoclave composed of stainless steel, was heated at 145° C. for three hours under stirring, and then was cooled. A product (1800 g) was extracted from the autoclave. The resulting solution was a transparent silica sol [Stringed silica sol A], and was used as the dispersion containing aggregated silicon oxide particles.

Stringed silica sol A had an SiO₂ content of 21.5 wt, a molar ratio SiO₂/Na₂O of 200, a pH of 9.62, a specific gravity of 1.141, a viscosity of 91.7 mPa·s, an electric conductivity of 3290 μS/cm, and a transmittance of 59.0%. The particle size (D1) determined by dynamic light scattering was 177 nm.

The ratio D1/D2 was 8.63. The silica sol was observed with an electron microscope to find colloidal silica particles composed of strings of 5 to 30 spherical silica colloidal particles in one plane and silica particles bonding spherical colloidal silica particles. No particles having a three-dimensional gel structure were found. The dried product of the sol was measured with a mercury porosimeter. The cumulative pore volume was 1.23 cc/g, and the average pore diameter was 49 nm.

### (Formation of Patterned Thin Metal Lines)

A pattern of thin metal lines was then printed on the surface having the anchor layer of the PET film in the same manner as in ACF-1.

### (Annealing of Patterned Thin Metal Lines)

After printing of the pattern of thin metal lines, the patterned thin metal lines were heat-treated on a hot plate at 120° C. for 30 minutes to prepare Transparent conductive substrate ACF-3.

### <Preparation of Transparent Conductive Substrate ACF-4>

Transparent conductive substrate ACF-3 was prepared as in ACF-3 except that the patterned thin metal lines were annealed by the following method.

### (Annealing of Patterned Thin Metal Lines)

After printing the patterned thin metal lines, the printed surface having the patterned thin metal lines was irradiated once for 2 milliseconds with a flash light having an irradiation energy of 2.5 J/cm² emitted from a xenon flash lamp 2400WS (available from COMET Corp.) equipped with a short wavelength (250 nm or less) cutting filter, so that the thermal annealing is performed.

### <Preparation of Transparent Conductive Substrates ACF-5 to ACF-11>

Transparent conductive substrates ACF-5 to ACF-11 were prepared as in ACF-4 except that with reference to Examples described in Japanese Patent Laid-open Publication No. 2007-169604 (process of forming an anchor layer in preparation of ACF-3), porous anchor layers (average thickness: 0.8 μm) were formed by varying the weight composition ratio of the inorganic compound in the anchor layer and the specific surface area of the anchor layer.

### <Preparation of Transparent Conductive Substrate ACF-12>

In preparation of ACF-4, with reference to Comparative Example 4 (Paragraph 0076) in Examples described in Japanese Patent Laid-open Publication No. 2007-169604, an anchor layer was formed such that the average dry thickness of the anchor layer was adjusted to 0.8 μm.

Specifically, “Dispersion” containing aggregated silicon oxide particles was prepared. Water (670 g), and then aqueous solution (210 g) containing 20 mass % of polyvinyl alcohol was subsequently added dropwise to “Dispersion” (120 g) under stirring. The solution was stirred at room temperature for one hour to prepare “Coating solution” having a solid concentration of 6 mass %. “Coating solution” was applied by bar coating such that the average dry thickness of the anchor layer was 0.8 μm, was heated at 120° C. for one minute, and was aged at 60° C. for three days. A porous anchor layer composed of 30 mass % of an inorganic compound was formed.

Except these, a pattern of thin metal lines was formed, and was annealed as in ACF-4 to prepare Transparent conductive substrate ACF-12.

### <Evaluation of Transparent Conductive Substrates>

In each of the above transparent conductive substrates, the specific surface area of the anchor layer, the average line width of the patterned thin metal lines, the separation of the patterned thin metal lines, the sheet resistance, and the sheet resistance after bending were evaluated by the procedures described below. The results are shown in Table 1.

### (1) Specific Surface Area of Anchor Layer

Two cut samples of 100 by 50 mm were prepared from each of the transparent conductive substrates after formation of the anchor layers. The cut samples were measured with a specific surface area measurement apparatus FlowSorb 112300 (available from SHIMADZU Corporation) by a nitrogen adsorption method (BET single-point method). The measured value was converted into a value per unit area to determine the specific surface area of the anchor layer.

### (2) Average Line Width of Patterned Thin Metal Lines

In each of the transparent conductive substrates, line widths at any 100 places of the patterned thin lines were measured with a CNC image evaluating system NEXIV VMR-1515 (available from NIKON CORPORATION) to determine the average value.

### (3) Separation of Patterned Thin Metal Lines

Cut samples having an appropriate size were prepared from the transparent conductive substrates. In each of the cut samples, the number of separations of the patterned thin metal lines in an area of 20 square millimeters was counted with an electron microscope Miniscope TM-1000 (available from Hitachi, Ltd.). The results were evaluated on the following criteria:

A: No separation

B: Separation(s) at 1 to 5 places

C: Separations at 6 or more places

D: Separations in almost all the thin metal lines

### (4) Sheet Resistance

Sheet resistance was measured with a resistivity meter Loresta GP (available from Daia Instruments Co., Ltd.) by a four-terminal method.

(5) Sheet Resistance after Bending

The transparent conductive substrates were each wound 10 times around a cylindrical rod having a diameter of 3 cm, and the sheet resistances after bending were measured in the same manner as in Item (4).

TABLE 1

| | | | | SPECIFIC | | | | |
|---|---|---|---|---|---|---|---|---|
| | | | | SUR- | PATTERNED THIN | | | |
| | ANCHOR LAYER | | | FACE | METAL LINES | | | |
| | | COMPOSITION | | AREA OF | AVERAGE | | | |
| CONDUCTIVE | | RATIO OF | ANNEALING | ANCHOR | LINE | | | |
| SUBSTRATE | | INORGANIC | BY FLASH | LAYER | WIDTH | | SHEET RESISTANCE [Ω/sq.] | |
| SAMPLE | FORMATION | COMPOUND [%] | LIGHT | [cm²/cm³] | [μm] | SEPARATION | INITIAL | AFTER BENDING |
| ACF-1; | — | — | — | — | 66 | A | 62 | 62 |
| COMPARATIVE | | | | | | | | |
| EXAMPLE | | | | | | | | |
| ACF-2; | — | — | ANNEALED | — | — | D | — | — |
| COMPARATIVE | | | | | | | | |
| EXAMPLE | | | | | | | | |
| ACF-3; | FORMED | 90 | — | 122 | 41 | A | 67 | 67 |
| COMPARATIVE | | | | | | | | |
| EXAMPLE | | | | | | | | |
| ACF-4 | FORMED | 90 | ANNEALED | 124 | 41 | A | 0.8 | 2 |
| ACF-5 | FORMED | 80 | ANNEALED | 118 | 43 | B | 1.0 | 6 |
| ACF-6 | | 75 | | 113 | 43 | B | 12 | 18 |
| ACF-7 | | 90 | | 32 | 48 | B | 8 | 11 |
| ACF-8 | | 90 | | 58 | 44 | A | 0.8 | 2 |
| ACF-9 | | 90 | | 271 | 38 | A | 0.8 | 3 |
| ACF-10 | | 90 | | 334 | 37 | A | 0.8 | 5 |
| ACF-11; | FORMED | 90 | ANNEALED | 26 | 53 | C | 84 | 96 |
| COMPARATIVE | | | | | | | | |
| EXAMPLE | | | | | | | | |
| ACF-12; | | 30 | | 17 | — | D | — | — |
| COMPARATIVE | | | | | | | | |
| EXAMPLE | | | | | | | | |

### (6) Summary

Table 1 evidently shows that Conductive substrates ACF-4 to ACF-10 prepared by the method according to the present invention have higher conductivities than those of Conductive substrates ACF 1 to 1-3 not having an anchor layer or not irradiated with flash light and those of Conductive substrate ACF 1 to 11 having a non-porous anchor layer (specific surface area of less than 30 cm²/cm²) and Conductive substrate ACF 1 to 12 not having an anchor layer mainly composed of an inorganic compound (proportion of the inorganic compound is less than 70% by mass) although these conductive substrates each have at least an anchor layer and are irradiated with flash light.

This is probably because the anchor layer according to the present invention prevents the separation of the patterned thin metal lines during thermal annealing of the patterned thin metal lines with flash light and thus ensures sufficient thermal annealing of the patterned thin metal lines by high-energy flash light.

It seems that the composition ratio of the inorganic compound in the anchor layer and the specific surface area of the anchor layer are important requirements to attain the advantageous effects of the anchor layer.

Consequently, formation of a porous anchor layer mainly composed of an inorganic compound and irradiation with flash light are useful in preparation of the conductive substrate.

### Example 2

A sample was prepared as in Example 1 except that that the pattern of thin metal lines was formed with a silver complex ink (TEC-IJ-010; available from InkTec Co., Ltd.), and was printed by an inkjet process.

The sample was evaluated as in Example 1. The results are similar to those of Example 1.

### Example 3

### Preparation of Organic EL Element AOL-30

### (Preparation of Transparent Conductive Substrate ACF-30)

An ITO transparent conductive layer (average thickness: 150 nm, dimensions: 50 by 50 mm) was formed on one surface of a clean alkali-free glass bare substrate (thickness: 0.7 mm, dimensions: 80 by 80 mm) by sputtering in accordance with a standard method to prepare Transparent conductive substrate ACF-30.

Transparent conductive substrate ACF-30 had a transmittance of 84% and a sheet resistance of 12 Ω/sq.

### (Preparation of Organic EL Element)

Transparent conductive substrate ACF-30 was used as a first electrode (anode), and Organic EL element AOL-30 was prepared by the following procedure.

PEDOT-PSS CLEVIOS P AI 4083 (solid content: 15%) (available from Heraeus Holding GmbH) was applied onto the conductive surface of Transparent conductive substrate ACF-30 as the first electrode with an applicator (coating width: 50 mm) such that the dry thickness of the coating was 30 nm. Excess coatings were wiped off to provide a coating of 50 square millimeters, and the coating wad dried.

ACF-30 was placed inside a commercially available vacuum deposition apparatus. Deposition crucibles in the vacuum deposition apparatus were filled with materials for layers in amounts optimal to preparation of the element. The deposition crucibles used were composed of a material for resistance heating, such as molybdenum or tungsten.

Organic compound layers were formed by the following procedures.

Pressure was reduced to a degree of vacuum 1×10⁻⁴ Pa, and then the deposition crucible containing α-NPD shown below was electrically heated to deposit α-NPD at a deposition rate of 0.1 nm/sec to form a hole transporting layer of 30 nm.

Ir-1, Ir-14, and Compound 1-7 shown below were co-deposited at a deposition rate of 0.1 nm/sec such that the content of Ir-1 was 13% by mass and that of Ir-14 was 3.7% by mass. A green-red phosphorescent layer having a maximum luminescent wavelength of 622 nm and a thickness of 10 nm was formed.

E-66 and Compound 1-7 were co-deposited at a deposition rate of 0.1 nm/sec such that the content of E-66 was 10% by mass. A blue phosphorescent layer having a maximum luminescent wavelength of 471 nm and a thickness of 15 nm was formed.

M-1 was deposited so as to have a thickness of 5 nm to form a hole blocking layer. Further, CsF was co-deposited with M-1 such that the thickness of CsF was 10% of the thickness of the M-1 layer. An electron transporting layer having a thickness of 45 nm was formed.

The compounds used for formation of the respective layers are shown:

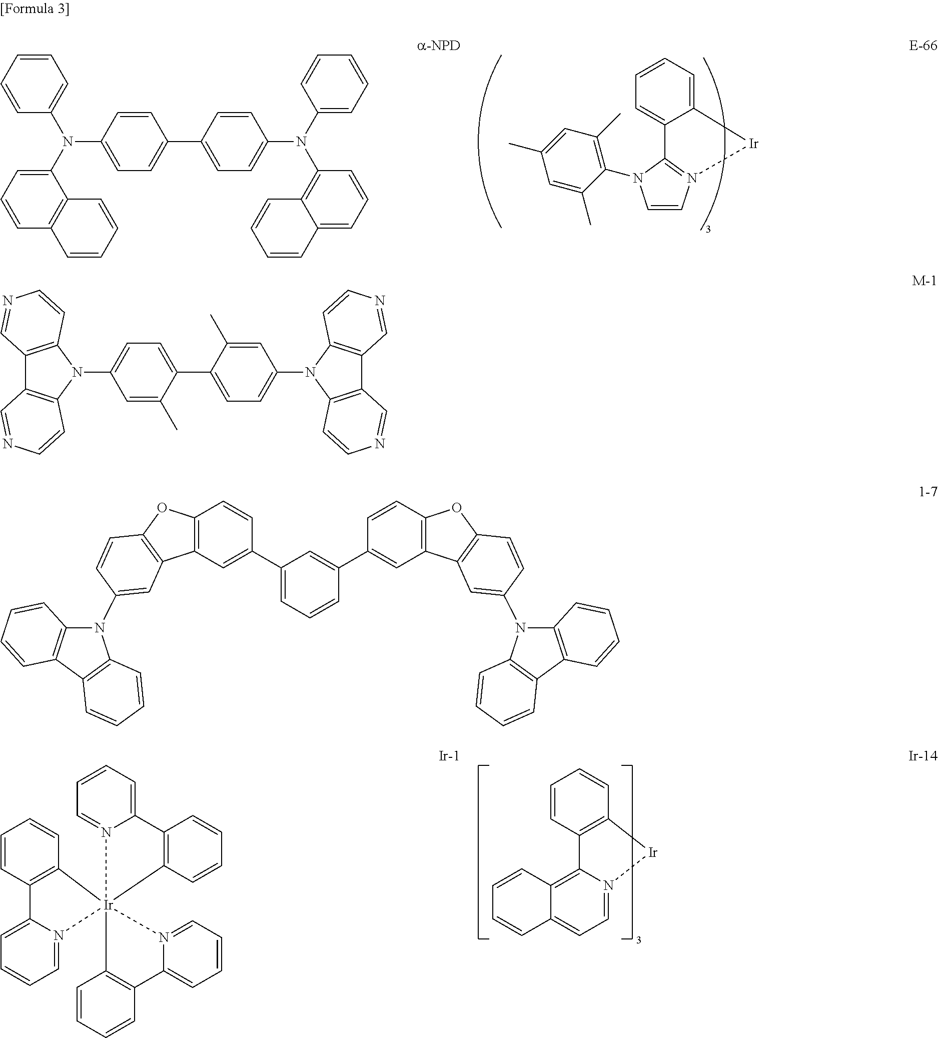

On the formed electron transporting layer, Al, which was a material for forming output terminals for a first electrode and a second electrode, was deposited through a mask under vacuum at 5×10⁻⁴ Pa to form a second electrode (cathode) having dimensions of 50 by 50 mm and a thickness of 100 nm.

An adhesive was applied to peripheral portions of the second electrode other than its ends so as to form output terminals for a first electrode and a second electrode, and a flexible encapsulating member composed of a polyethylene terephthalate resin film as a bare substrate and Al₂O₃ with a thickness of 300 nm deposited on the film was bonded thereto. The adhesive was then cured by heating to dispose an encapsulating film to prepare Organic EL element AOL-30 having a luminous area of 50 by 50 mm.

The adhesive used was prepared by compounding two liquid epoxy resins (available from ThreeBond Holdings Co., Ltd.) 2016B and 2103 in a ratio of 100:3.

### <Preparation of Organic EL Element AOL-31>

Organic EL element AOL-31 was prepared as in Organic EL element AOL-30 except that a transparent conductive substrate was prepared by the following method and was used as a first electrode (anode).

### (Preparation of Transparent Conductive Substrate ACF-31)

With reference to Example 2 (Paragraph 0065) described in Japanese Patent Laid-open Publication No. 2007-169604, a coating solution for an anchor layer was prepared, and was applied to one surface of a clean alkali-free glass bare substrate (thickness: 0.7 mm, dimensions: 80 by 80 mm) with an applicator (coating width: 50 mm).

Specifically, “Dispersion” containing aggregated silicon oxide particles was prepared. Glycidoxypropyltrimethoxysilane (306.84 g) and titanium tetraisopropoxide (266.87 g) were dissolved in ethyl cellosolve (257.26 g). A mixed solution of concentrated nitric acid (100.68 g), water (31.61 g), and ethyl cellosolve (36.75 g) was added dropwise to the solution. The resulting solution was allowed to stand at 30° C. for four hours for reaction to prepare “Binder solution” having a solid concentration of 30% by mass.

Cyclohexanone (620 g), and then Binder solution (20 g) was sequentially added dropwise to the dispersion (360 g) with stirring. The resulting solution was stirred at room temperature for one hour to prepare “Coating solution” having a solid concentration of 6% by mass.

The coating solution was then applied to one surface of a clean alkali-free glass bare substrate (thickness: 0.7 mm, dimensions: 80 by 80 mm) with an applicator (coating width: 50 mm).

Excess peripheral coatings were wiped off, and a pattern of 50 by 50 mm was formed. The patterned substrate was heated at 120° C. for one minute, and was aged at 60° C. for three days to prepare a porous anchor layer having an average dry thickness of 0.8 μm and composed of 90% by mass of an inorganic compound. The anchor layer had a specific surface area of 125 cm²/cm².

A pattern of thin metal lines was printed on the anchor layer with a silver nanoparticle ink (TEC-PR-030; available from InkTec Co., Ltd.). The printing was conducted through a gravure printing pattern of a square lattice having a width of 30 μm and a pitch of 0.75 mm such that the average height of the thin lines was 0.8 μm. A compact thick-film semi-automatic printing machine STF-1501P (available from Tokai Shoji Co., Ltd.) was used. The pattern was printed in an area of 50 square millimeters.

The printed surface of the patterned thin metal lines was then irradiated once for 2 milliseconds with a flash light having an irradiation energy of 2.5 J/cm² emitted from a xenon flash lamp 2400WS (available from COMET Corp.) equipped with a short wavelength (250 nm or less) cutting filter, so that the thermal annealing is performed. The patterned thin metal lines after thermal annealing had a sheet resistance of 2 Ω/sq.

A water-soluble binder resin prepared by the following procedure was added to a conductive polymer dispersion of PEDOT:PSS (polystyrene sulfonic acid)=1:2.5, which is available from Heraeus Holding GmbH under the trade name CLEVIOS PH510 (solid concentration: 1.89%), such that the solid content was 75%. Conductive polymer solution CP-1 was prepared, and was applied onto the patterned thin metal lines after thermal annealing by irradiation of flash light with an applicator having a coating width of 50 mm, which corresponded to the printing width of the patterned thin metal lines. Conductive polymer solution CP-1 was applied such that the conductive polymer layer to be formed had an average dry thickness of 500 nm, and excess peripheral coatings were wiped off in correspondence with the printed regions of the patterned thin metal lines. The coating was dried with visible to near-infrared light, which is barely absorbed by PET films, in a dryer equipped with an NIR(R) emitter available from Adphos Innovative Technologies GmbH as a light source. Transparent conductive substrate ACF-31 was prepared.

Transparent conductive substrate ACF-31 had a transmittance of 83% and a sheet resistance of 0.8 Ω/sq.

The cross section of a transparent conductive substrate prepared in the same manner was observed with an electron microscope to find that the conductive polymer layer permeated the anchor layer and was over the surface of the anchor layer.

### (Preparation of Water-Soluble Binder Resin)

Tetrahydrofuran (THF, 200 ml) was placed in a 300 ml three-necked flask, was heated under reflux for 10 minutes, and was cooled to room temperature under nitrogen. 2-Hydroxyethyl acrylate (10.0 g, 86.2 mmol, molecular weight: 116.12) and azoisobutyronitrile (2.8 g, 17.2 mmol, molecular weight: 164.11) were added, and were heated under reflux for 5 hours. After the solution was cooled to room temperature, the reaction solution was added dropwise to methyl ethyl ketone (MEK, 2000 ml), and was stirred for one hour. After MEK was decanted, the resulting polymer was washed with MEK (100 ml) three times. The polymer was dissolved in THF, and was transferred into a 100 ml flask. After THF was distilled off under reduced pressure with a rotary evaporator, the product was dried under reduced pressure at 50° C. for three hours. A water-soluble binder resin (9.0 g, yield: 90%) having a number-average molecular weight of 22100 and a molecular weight distribution of 142 was prepared.

The structure and the molecular weight thereof were determined by ¹H-NMR (400 MHz, available from JEOL, Ltd.) and GPC (Waters 2695, available from Waters Corporation).

### <Operating Conditions on GPC>

### Apparatus: Waters 2695 (Separations Module)

### Detector: Waters 2414 (Refractive Index Detector)

### Column: Shodex Asahipak GF-7M HQ

Eluent: dimethylformamide (20 mM LiBr)
Flow rate: 1.0 ml/min

### Temperature: 40° C.

The water-soluble binder resin was dissolved in pure water to prepare an aqueous solution of the water-soluble binder resin having a solid content of 20%.

### <Preparation of Organic EL Element AOL-32>

Organic EL element AOL-31 was prepared as in Organic EL element AOL-31 except that a transparent conductive substrate was prepared by the following method and was used as a first electrode (anode).

### (Preparation of Transparent Conductive Substrate ACF-32)

Transparent conductive substrate ACF-32 was prepared as in Transparent conductive substrate ACF-31 except that no anchor layer was disposed on the glass bare substrate and the patterned thin metal lines were directly formed on the glass bare substrate.

Transparent conductive substrate ACF-32 had a transmittance of 85% while the sheet resistance was not measured because the patterned thin metal lines were separated from the bare substrate.

### <Preparation of Organic EL Element AOL-33>

Organic EL element AOL-33 was prepared as in Organic EL element AOL-30 except that a transparent conductive substrate was prepared by the following method and was used as a first electrode (anode).

### (Preparation of Transparent Conductive Substrate ACF-33)

A transparent film substrate including a barrier layer was prepared in the manner described below. An ITO transparent conductive layer (average thickness: 150 nm, dimensions: 50 by 50 mm) was formed on the barrier layer by sputtering in accordance with a standard method to prepare Transparent conductive substrate ACF-33.

Transparent conductive substrate ACF-33 had a transmittance of 82% and a sheet resistance of 35 Ω/sq.

### (Preparation of Transparent Film Substrate Including Barrier Layer)

### (Formation of Barrier Layer)

A solution of 20% by mass perhydropolysilazane (PHPS, AQUAMICA NN320 available from AZ Electronic Materials plc) in dibutyl ether was applied to one surface of a polyethylene terephthalate (PET) film (thickness: 110 μm, dimensions: 80 by 80 mm) having hard coat layers on both surfaces thereof, such that the average film thickness was 0.3 μm. The PET film was dried under an atmosphere of 85° C. and 55% RH for one minute, and then was defumidified under an atmosphere of 25° C. and 10% RH (dew point temperature: −8° C.) for 10 minutes.

The dehumidified sample was modified on the following conditions to prepare a transparent film bare substrate including a barrier layer. The dew point temperature during modification was −8° C.

### <Modifying Apparatus>

An excimer irradiation apparatus (available from M.D.COM., Inc., MODEL: MECL-M-1-200, wavelength: 172 nm, gas contained in the lamp: Xe) was used. The sample was fixed on a movable stage, and was modified under the following conditions:

### <Modifying Conditions>

Intensity of excimer light: 60 mW/cm² (172 nm)
Distance between the sample and the light source: 1 mm
Temperature to heat the stage: 70° C.
Concentration of oxygen in the irradiation apparatus: 1%
Irradiation time of excimer: 3 seconds

The water vapor transmittance of the transparent film bare substrate including a barrier layer was determined by a Ca method. The water vapor transmittance was 2×10⁻⁵ (g·m²·day).

### <Preparation of Organic EL Element AOL-34>

Organic EL element AOL-34 was prepared as in Organic EL element AOL-31 except that a transparent conductive substrate was prepared by the following method and was used as a first electrode (anode).

### (Preparation of Transparent Conductive Substrate ACF-34)

With reference to Example 2 (Paragraph 0065) described in Japanese Patent Laid-open Publication No. 2007-169604, a coating solution for an anchor layer was prepared, and was applied onto a barrier layer of a transparent film bare substrate including a barrier layer with an applicator (coating width 50 mm), the barrier layer being the same as that used in Transparent conductive substrate ACF-33.

Specifically, “Dispersion” containing aggregated silicon oxide particles was prepared. Glycidoxypropyltrimethoxysilane (306.84 g) and titanium tetraisopropoxide (266.87 g) were dissolved in ethyl cellosolve (257.26 g), and a mixed solution of concentrated nitric acid (100.68 g), water (31.61 g), and ethyl cellosolve (36.75 g) was added dropwise to the solution. The resulting solution was allowed to stand at 30° C. for four hours for reaction to prepare “Binder solution” having a solid concentration of 30% by mass.

After that, cyclohexanone (620 g), and then Binder solution (20 g) was sequentially added dropwise to the above dispersion (360 g) with stirring. The resulting solution was stirred at room temperature for one hour to prepare “Coating solution” having a solid concentration of 6% by mass.

The above coating solution was then applied onto the barrier layer of the transparent film bare substrate with an applicator (coating width: 50 mm).

Excess peripheral coatings were wiped off, and a pattern of 50 by 50 mm was formed. The patterned substrate was heated at 120° C. for one minute, and was aged at 60° C. for three days to prepare a porous anchor layer having an average dry thickness of 0.8 μm and composed of 90% by mass of an inorganic compound. The anchor layer had a specific surface area of 122 cm²/cm².

Transparent conductive substrate ACF-34 was prepared as in Transparent conductive substrate ACF-31 except that the transparent film bare substrate including a barrier layer and an anchor layer was used in place of the glass bare substrate in ACF-31.

Transparent conductive substrate ACF-34 had a transmittance of 82% and a sheet resistance of 0.8 Ω/sq.

### <Preparation of Organic EL Element AOL-35>

Organic EL element AOL-35 was prepared as in Organic EL element AOL-34 except that a transparent conductive substrate was prepared by the following method and was used as a first electrode (anode).

### (Preparation of Transparent Conductive Substrate ACF-35)

Transparent conductive substrate ACF-35 was prepared as in Transparent conductive substrate ACF-34 except that no anchor layer was disposed on the transparent film bare substrate including a barrier layer and the pattern of thin metal lines was directly formed on the barrier layer.

Transparent conductive substrate ACF-35 had a transmittance of 84% while the sheet resistance was not measured because the patterned thin metal lines were separated from the substrate.

### <Evaluation of Organic EL Elements>

In Organic EL elements AOL-30 to AOL-35, the light extraction efficiency was evaluated by the following method.

### (1) Measurement of Luminous Efficacy

In Organic EL elements AOL-30 to AOL-35, DC voltage was applied with a Source Measure Unit 2400 available from Keithley Instruments Inc. to make the organic EL element emit light at 300 cd, and the luminous efficacy (lumen/W) at this time was measured. The luminous efficacy of AOL-30 was defined as 100, and the luminous efficacies of the other organic EL elements were expressed relative to the luminous efficacy of AOL-30 in Table 2.

Since Organic EL elements AOL-30 to AOL-35 have the same configuration of the organic layer, a difference in luminous efficacy can be considered mainly as a difference in light extraction efficiency.

AOL-32 and AOL-35 did not emit light due to a short circuit between the first electrode and the second electrode, which was probably caused by the separation of the patterned thin metal lines.

TABLE 2

| ORGANIC EL | | FORMATION | | FORMATION OF |
|---|---|---|---|---|
| ELEMENT | | OF BARRIER | CONFIGURATION | ANCHOR |
| SAMPLE | SUBSTRATE | LAYER | ELECTRODE | LAYER |
| AOL-30: | GLASS | — | ITO | — |
| COMPARATIVE | | | | |
| EXAMPLE | | | | |
| AOL-31: | GLASS | — | PATTERNED THIN METAL | FORMED |
| | | | LINES + CONDUCTIVE | |
| | | | POLYMER LAYER | |
| AOL-32: | GLASS | — | PATTERNED THIN METAL | — |
| COMPARATIVE | | | LINES + CONDUCTIVE | |
| EXAMPLE | | | POLYMER LAYER | |
| AOL-33: | FILM | FORMED | ITO | — |
| COMPARATIVE | | | | |
| EXAMPLE | | | | |
| AOL-34 | FILM | FORMED | PATTERNED THIN METAL | FORMED |
| | | | LINS + CONDUCTIVE | |
| | | | POLYMER LAYER | |
| | FILM | FORMED | PATTERNED THIN METAL | — |
| AOL-35: | | | LINES + CONDUCTIVE | |
| COMPARATIVE | | | POLYMER LAYER | |
| EXAMPLE | | | | |

| ORGANIC EL | | | SHEET | LIGHT |
|---|---|---|---|---|
| ELEMENT | ANNEALING BY | TRANSMITTANCE | RESISTANCE | EXTRACTION |
| SAMPLE | FLASH LIGHT | [%] | [Ω/sq.] | EFFICIENCY |
| AOL-30: | — | 84 | 12 | 100 |
| COMPARATIVE | | | | |
| EXAMPLE | | | | |
| AOL-31: | ANNEALED | 83 | 0.8 | 135 |
| AOL-32: | ANNEALED | 85 | — | — |
| COMPARATIVE | | | | |
| EXAMPLE | | | | |
| AOL-33: | — | 82 | 35 | 103 |
| COMPARATIVE | | | | |
| EXAMPLE | | | | |
| AOL-34 | ANNEALED | 82 | 0.8 | 140 |
| AOL-35: | ANNEALED | 84 | — | — |
| COMPARATIVE | | | | |
| EXAMPLE | | | | |

### (2) Summary

Table 2 evidently shows that Organic EL elements AOL-31 and AOL-34, each including the transparent conductive substrate as the first electrode prepared by the method according to the present invention, have higher light extraction efficiencies than those of Organic EL element AOL-30 and AOL-33 including the conventional ITO transparent electrodes and Organic EL elements AOL-32 and AOL-35 with no anchor layer.

Such an improvement in the light extraction efficiency by the transparent conductive substrate prepared by the method according to the present invention is an unexpected advantage brought by the present invention probably because a conductive polymer layer is also formed inside the porous anchor layer mainly composed of an inorganic compound and light is scattered in the anchor layer due to the difference in the refractive index between the inorganic compound and the polymer component, although its mechanism is unclear.

### INDUSTRIAL APPLICABILITY

The method according to the present invention can be particularly suitably applied to production of highly conductive substrates with less or no damage to the bare substrate and the patterned thin metal lines.

### REFERENCE SIGNS LIST

1 Conductive substrate
2 Bare substrate
4 Barrier layer
6 Anchor layer
8 Patterned thin metal lines
10 Conductive polymer layer
20 Organic electronic element
22 First electrode
24 Organic functional layer
26 Second electrode

1. A method for producing a conductive substrate including at least an anchor layer and a pattern of conductive thin metal lines on a bare substrate, the method comprising the steps of:
forming a porous anchor layer mainly composed of an inorganic compound on the bare substrate;
forming the pattern of thin metal lines containing metal nanoparticles and a metal complex on the anchor layer; and
performing thermal annealing of the pattern of thin metal lines by irradiation of flash light.

2. The method for producing the conductive substrate according to claim 1,
wherein the bare substrate is composed of a resin substrate.

3. The method for producing the conductive substrate according to claim 2, the method further comprising:
a step of forming a barrier layer between the bare substrate and the anchor layer.

4. The method for producing the conductive substrate according to claim 3,
wherein the bare substrate, the anchor layer, and the barrier layer are transparent.

5. The method for producing the conductive substrate according to claim 1, the method further comprising:
a step of forming a conductive polymer layer containing at least a n-conjugated conductive polymer and polyanion on the pattern of thin metal lines after the thermal annealing step.

6. A conductive substrate produced by the method for producing the conductive substrate according to claim 1.

7. An organic electronic element comprising:
the conductive substrate produced by the method for producing the conductive substrate according to claim 1;
a second electrode disposed opposite to the conductive substrate; and
an organic functional layer disposed between the conductive substrate and the second electrode.
